(19) United States
(12) Patent Application Publication
(10) Pub. No.: US 2013/0235685 A1
(43) Pub. Date: Sep. 12, 2013

(54) SEMICONDUCTOR MEMORY DEVICE AND METHOD OF SCREENING THE SAME

(71) Applicant: SAMSUNG ELECTRONICS CO., LTD., Suwon-si (KR)

(72) Inventors: Hong Beom Kim, Hwaseong-si (KR); Kab Yong Kim, Suwon-si (KR)

(73) Assignee: SAMSUNG ELECTRONICS CO., LTD., Suwon-si (KR)

(21) Appl. No.: 13/788,453

(22) Filed: Mar. 7, 2013

(30) Foreign Application Priority Data
Mar. 7, 2012 (KR) 10-2012-0023596

(51) Int. Cl. G11C 29/08

(52) U.S. Cl. CPC G11C 29/08
USPC 365/201

(57) ABSTRACT

A semiconductor memory device may include a voltage comparator, a voltage generator, a counter, and a circuit. The voltage comparator may be configured to generate an enabling signal responsive to a comparison indicating that a first voltage is lower than a reference voltage. The voltage generator may be configured to generate oscillation signals and a boost voltage by boosting the first voltage and to feed the boost voltage back as the first voltage in response to the enabling signal. The counter may be configured to count the number of the oscillation signals, and to generate a count output signal having information corresponding to the number of the oscillation signals. The circuit may be configured to output the count output signal as a quality output signal indicating the counted number relative to a target set value.

### CROSS-REFERENCE TO RELATED APPLICATIONS

This application claims the benefit of Korean Patent Application No. 10-2012-0023596, filed on Mar. 7, 2012, in the Korean Intellectual Property Office, the disclosure of which is incorporated herein in its entirety by reference.

### BACKGROUND

Example embodiments relate to a semiconductor memory device, and more particularly, to a semiconductor memory device to screen whether each word line of a memory array is shorted, and a method for screening operation of the semiconductor memory device.

Semiconductor products need to be screened on whether word lines (WLs) are bad. Although methods of reducing a test time by testing a plurality of row addresses at once have been proposed, the reduction of a test time causes a decrease in discrimination. Thus, a technology of detecting bad WLs among all the WLs within a short time is beneficial.

### SUMMARY

Embodiments of the disclosure provide a boost voltage generation circuit for screening quality of a semiconductor memory device.

According to one embodiment, there is provided a semiconductor memory device. The semiconductor memory device includes a voltage comparator, a voltage generator, a counter, and a circuit. The voltage comparator is configured to generate an enabling signal responsive to a comparison indicating that a first voltage is lower than a reference voltage. The voltage generator is configured to generate oscillation signals and a boost voltage by boosting the first voltage and to feed the boost voltage back as the first voltage in response to the enabling signal. The counter is configured to count the number of the oscillation signals, and to generate a count output signal having information corresponding to the number of the oscillation signals. The circuit is configured to output the count output signal as a quality output signal indicating the counted number is equal to or greater than relative to a target set value.

According to another embodiment, there is provided a memory device. The memory device includes a memory cell array, a voltage comparator, an oscillator, a voltage generator, a counter, a determiner, and a row decoder. The memory cell array includes memory cells corresponding to a plurality of word lines. The voltage comparator is configured to generate an enabling signal resulting from a comparison indicating a first voltage is lower than a reference voltage. The oscillator is configured to generate oscillation signals in response to the enabling signal. The voltage generator is configured to generate a boost voltage by boosting the first voltage in response to the oscillation signals. The counter is configured to count the number of the oscillation signals, and to generate a count output signal responsive to the number of the oscillation signals. The circuit is configured to output the count output signal as a quality output signal indicating whether the memory device is good or bad. The row decoder is configured to provide the first voltage to a selected one of the word lines.

According to another embodiment, there is provided a method for screening operation of a memory device. The method includes comparing a first voltage with a reference voltage, generating an enabling signal in response to the result of comparison, generating oscillation signals in response to the enabling signal, boosting the first voltage in response to the oscillation signals, counting the number of oscillation signals and outputting a count output signal in response to the counting, and in response to the count output signal, and outputting the count output signal as a quality output signal indicating whether the memory device is bad.

### BRIEF DESCRIPTION OF THE DRAWINGS

Exemplary embodiments will be more clearly understood from the following detailed description taken in conjunction with the accompanying drawings in which:

FIG. 1 is a block diagram of a boost voltage generation circuit according to an exemplary embodiment;

FIG. 2 illustrates waveforms showing a change in a boost voltage in response to an enabling signal in the boost voltage generation circuit of FIG. 1 according to an embodiment;

FIG. 3 is a block diagram of a boost voltage generation circuit according to another embodiment;

FIG. 4 is a block diagram of a boost voltage generation circuit according to another embodiment;

FIG. 5 is a block diagram of a boost voltage generation circuit according to another embodiment;

FIG. 6 is a block diagram of a boost voltage generation circuit according to another embodiment;

FIG. 7A is a block diagram of a counter included in a boost voltage generation circuit, according to an embodiment;

FIG. 7B is a block diagram of the counter included in a boost voltage generation circuit, according to another embodiment;

FIG. 8 is a block diagram of the counter of FIG. 7A and a determiner included in a boost voltage generation circuit, according to an embodiment;

FIG. 9 is a timing diagram illustrating an operation of the device of FIG. 8 according to an embodiment;

FIG. 10 is a flowchart illustrating a method of determining whether a semiconductor memory device is bad, according to an embodiment;

FIG. 11 is a block diagram of a Double Data Rate Synchronous Dynamic Random Access Memory (DDR-SDRAM) as an example of a semiconductor memory device according to an embodiment;

FIG. 12 is a block diagram of an application example of an electronic system including a semiconductor memory device, according to an embodiment;

FIG. 13 is a block diagram of a first application example of a memory system including a semiconductor memory device, according to an embodiment;

FIG. 14 is a block diagram of a second application example of a memory system including a semiconductor memory device, according to another embodiment; and

FIG. 15 is a block diagram of a computer system including a semiconductor memory device, according to an embodiment.

### DETAILED DESCRIPTION OF THE EMBODIMENTS

Various embodiments will now be described more fully with reference to the accompanying drawings in which some example embodiments are shown. This present disclosure may, however, be embodied in different forms and should not be construed as limited to the embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. Unless indicated otherwise, these terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present inventive concept. As used herein, the singular forms “a,” “an” and “the” are intended to include the plural forms as well, unless the context clearly indicates otherwise. It will be further understood that the terms such as “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

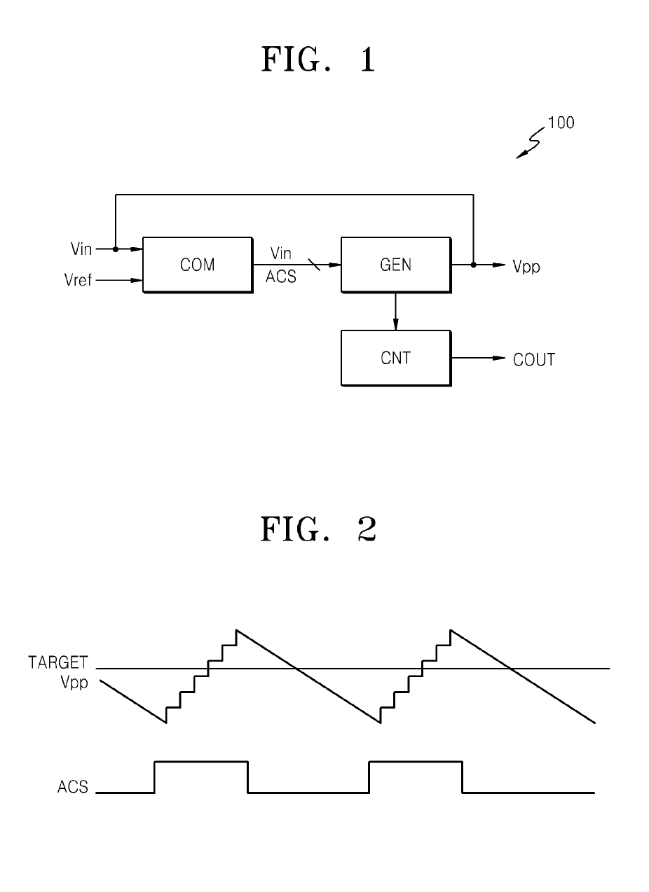

FIG. 1 is a block diagram of a boost voltage generation circuit 100 according to an embodiment.

Referring to FIG. 1, the boost voltage generation circuit 100 includes a voltage comparator COM, a voltage generator GEN, and a counter CNT.

The boost voltage generation circuit 100 may be included in a semiconductor memory device. For example, the semiconductor memory device may be a Dynamic Random Access Memory (DRAM). However, the semiconductor memory device is not limited to the DRAM and may be a Random Access Memory (RAM), a Read Only Memory (ROM), a Synchronous DRAM (SDRAM), any of different types of memories including a NAND flash memory and a NOR flash memory, or any of other large-capacity storage devices, such as a Solid State Disk (SSD) and a Hard Disk Drive (HDD), which may be provided as semiconductor integrated circuits in Personal Computers (PCs) and other electronic devices.

The voltage comparator COM compares an input voltage Vin with a predetermined reference voltage Vref. The voltage comparator COM outputs an enabling signal ACS according to a comparison result.

The voltage generator GEN receives the enabling signal ACS and the input voltage Vin from the voltage comparator COM. The voltage generator GEN generates a boost voltage Vpp by increasing the input voltage Vin by a specific value in response to the enabling signal ACS. If a level of the boost voltage Vpp is equal to or greater than a predetermined target level, the voltage comparator COM does not output the enabling signal ACS. In this case, the voltage generator GEN does not perform a voltage boosting operation any more, thereby causing the boost voltage Vpp to maintain a stable level.

The counter CNT counts the number of voltage boosting operations until the boost voltage Vpp maintains a stable level. If the number of voltage boosting operations is equal to or greater than a predetermined value, a corresponding word line of a semiconductor memory device may be determined as bad. Otherwise, if the number of voltage boosting operations is less than the predetermined value, the corresponding word line of the semiconductor memory device may be determined as good. The counter CNT may output whether the number of voltage boosting operations is equal to or greater than the predetermined value. In one embodiment, the counter CNT may output the number of voltage boosting operations as an output signal COUT.

The determination on whether a word line of a semiconductor memory device is bad may be performed in a quality check stage after semiconductor production. Alternatively, the determination on whether a word line of the semiconductor memory device is bad may be performed in the use of a corresponding semiconductor memory device. Alternatively, the determination on whether a word line of a semiconductor memory device is bad may be performed every time the boost voltage Vpp is output. Alternatively, the determination on whether a word line of a semiconductor memory device is bad may be performed for every row address.

If a word line of the semiconductor memory device is determined as bad, the word line of a corresponding address may be not used. For example, if a word line of the semiconductor memory device is determined as bad, the word line determined as bad may be replaced with a redundant word line.

FIG. 2 illustrates waveforms showing a change in the boost voltage Vpp in response to the enabling signal ACS in the boost voltage generation circuit 100 of FIG. 1 according to an embodiment.

Referring to FIG. 2, the voltage generator GEN continuously increases the input voltage Vin while continuously receiving the enabling signal ACS. In FIG. 2, 5 voltage boosting operations are described as an example. In this case, the counter CNT counts 5. Accordingly, the voltage generator GEN increases the input voltage Vin 5 times. In addition, the voltage generator GEN performs 5 feedbacks to the voltage comparator COM. For example, it may be determined that the number of voltage boosting operations counted by the counter CNT is less than a target set value. That is, it may be determined that a corresponding word line of the semiconductor memory device is not bad. If the number of voltage boosting operations counted by the counter CNT is equal to or greater than the target set value, it indicates that the reference voltage Vref is still higher than the input voltage Vin. When the counted number is equal to or greater than the target set value, a semiconductor memory device may indicate that the corresponding word line is shorted with a corresponding bit line through a micro bridge. In one embodiment, for example, if the counted number is equal to or greater than 8, a semiconductor memory device may be determined as bad. However, whether each semiconductor memory device is determined as bad when the counted number is equal to or greater than a predetermined number may vary according to application examples of each semiconductor memory device and does not limit the scope of the disclosure.

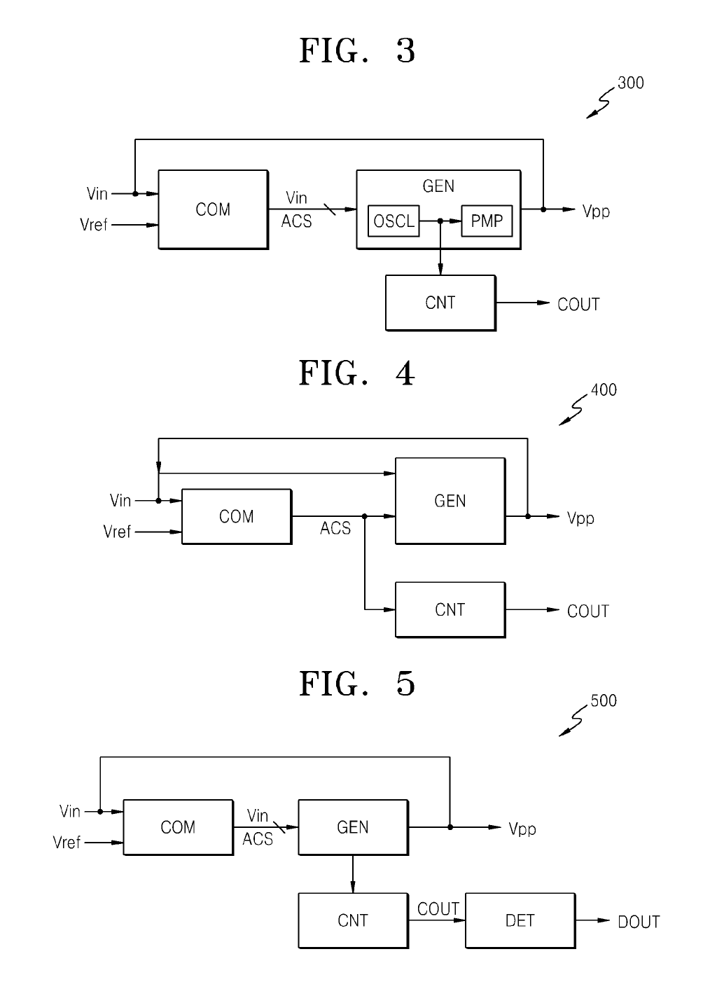

FIG. 3 is a block diagram of a boost voltage generation circuit 300 according to second embodiment.

Referring to FIG. 3, like the boost voltage generation circuit 100 of FIG. 1, the boost voltage generation circuit 300 includes the voltage comparator COM, the voltage generator GEN, and the counter CNT. However, the voltage generator GEN of the boost voltage generation circuit 300 may include an oscillator OSCL and a pumping circuit PMP. The oscillator OSCL may be, for example, a ring oscillator. The oscillator OSCL performs one ore more periods of oscillation in response to the enabling signal ACS. During the one period of oscillation, the counter CNT may perform a counting operation once. During the one period of oscillation, the pumping circuit PMP increases the input voltage Vin by the specific value and outputs the boost voltage Vpp. In one embodiment, the counting operation is performed in response to a signal output from the oscillator OSCL. The counter CNT may be connected to the oscillator OSCL to perform the counting operation.

FIG. 4 is a block diagram of a boost voltage generation circuit 400 according to third embodiment.

Referring to FIG. 4, like the boost voltage generation circuit 100 of FIG. 1, the boost voltage generation circuit 400 includes the voltage comparator COM, the voltage generator GEN, and the counter CNT. However, the counter CNT of the boost voltage generation circuit 400 may count the number of voltage boosting operations by receiving the enabling signal ACS. In one embodiment, if the counter CNT counts the number of the enabling signal ACS, the counter CNT may count the number of oscillations in a state where the counter CNT is not directly connected to the voltage generator GEN. For example, the counter CNT may count the number of oscillations by dividing a duration time of the enabling signal ACS by one period of the oscillations. In one embodiment, the counter CNT may count the number of oscillations by dividing a time obtained by subtracting a transition time from the duration time of the enabling signal ACS by one period of the oscillations.

FIG. 5 is a block diagram of a boost voltage generation circuit 500 according to fourth embodiment.

Referring to FIG. 5, like the boost voltage generation circuit 100 of FIG. 1, the boost voltage generation circuit 500 includes the voltage comparator COM, the voltage generator GEN, and the counter CNT. However, the counter CNT of the boost voltage generation circuit 500 is connected to a determiner DET. The determiner DET may receive a counter output signal COUT. The determiner DET may determine that a word line of a semiconductor memory device to be checked is bad when the counter CNT counts a value equal to or greater than a predetermined number. The determiner DET may output a determination result on whether a word line of a semiconductor memory device to be checked is bad. For example, the determiner DET may output a quality output signal DOUT as low to indicate that a word line of a semiconductor memory device to be checked is bad.

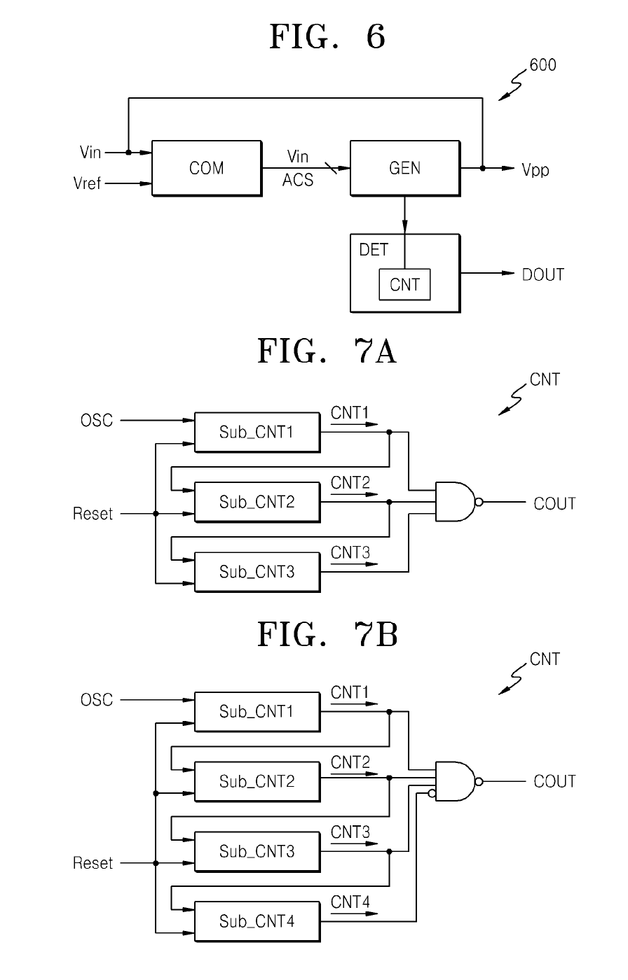

FIG. 6 is a block diagram of a boost voltage generation circuit 600 according to fifth embodiment.

Referring to FIG. 6, like the boost voltage generation circuit 100 of FIG. 1, the boost voltage generation circuit 600 includes the voltage comparator COM, the voltage generator GEN, and the counter CNT. However, a determiner DET of the boost voltage generation circuit 600 may include the counter CNT. In one embodiment, the determiner DET may indirectly count the number of oscillations. For example, a value obtained by dividing a difference between a final boost voltage Vpp and an input voltage Vin initially input to the voltage comparator COM by a voltage that is increased once may be the number of oscillations. Here, the input voltage Vin may indicate a voltage initially input to the boost voltage generation circuit 600. In addition, the final boost voltage Vpp may indicate the reference voltage Vref. In one embodiment, the determiner DET may obtain the number of oscillations from a value obtained by dividing a difference between the reference voltage Vref and the input voltage Vin by the voltage that is increased once.

FIG. 7A is a block diagram of the counter CNT included in a boost voltage generation circuit, according to an embodiment.

Referring to FIG. 7A, the counter CNT may include a first sub-counter Sub_CNT1, a second sub-counter Sub_CNT2, and a third sub-counter Sub_CNT3. Each of the first, second, and third sub-counters Sub_CNT1, Sub_CNT2, and Sub_CNT3 may have an output corresponding to a reset signal Reset, an oscillation signal OSC, and another sub-count signal (first or second sub-count signal CNT1 or CNT2).

For example, the first sub-counter Sub_CNT1 may receive the oscillation signal OSC and the reset signal Reset and output the first sub-count signal CNT1. The second sub-counter Sub_CNT2 may receive the first sub-count signal CNT1 and the reset signal Reset and output the second sub-count signal CNT2. The third sub-counter Sub_CNT3 may receive the second sub-count signal CNT2 and the reset signal Reset and output a third sub-count signal CNT3. The first to third sub-count signals CNT1, CNT2, and CNT3 may be input to a NAND gate, and the NAND gate may output the counter output signal COUT.

For example, the first to third sub-count signals CNT1, CNT2, and CNT3 may be reset as low by the reset signal Reset. The first sub-count signal CNT1 may be triggered by a rising edge or a falling edge of the oscillation signal OSC. The second sub-counter Sub_CNT2 may be triggered by a rising edge or a falling edge of the first sub-count signal CNT1. The third sub-count signal CNT3 may be triggered by a rising edge or a falling edge of the second sub-counter Sub_CNT2. When all of the first to third sub-count signals CNT1, CNT2, and CNT3 are high, the counter output signal COUT may be low or high.

A combination of the first to third sub-count signals CNT1, CNT2, and CNT3 may indicate any one of 0 to 7. For example, when all of the first to third sub-count signals CNT1, CNT2, and CNT3 are high, the counter output signal COUT may indicate a binary number 111. In this case, a combination of the first to third sub-count signals CNT1, CNT2, and CNT3 may indicate 7. This indicates that the oscillation signal OSC has oscillated 7 times.

Thus, when the first to third sub-count signals CNT1, CNT2, and CNT3 are input to the NAND gate, the counter output signal COUT may be low. Accordingly, in response to the counter output signal COUT of the counter CNT of the one embodiment in a case where the number of oscillations is 7 or a case where the input voltage Vin has been increased 7 times, it may be determined that a corresponding word line of a semiconductor memory device to be checked is bad.

In one embodiment, each of the first to third sub-count signals CNT1, CNT2, and CNT3 may be connected to respective external terminals (not shown). For example, the first sub-count signals CNT1 is connected to a first external terminal DQ1, the second sub-count signals CNT2 is connected to a second external terminal DQ2, and the third sub-count signals CNT3 is connected to a third external terminal DQ3. The controller (not shown) may recognize the number of oscillation signals by receiving the first to third sub-count signals CNT1, CNT2, and CNT3 through the first to third external terminals DQ1, DQ2, and DQ3.

FIG. 7B is a block diagram of the counter CNT included in a boost voltage generation circuit, according to another embodiment.

Referring to FIG. 7B, the counter CNT may include a first sub-counter Sub_CNT1, a second sub-counter Sub_CNT2, a third sub-counter Sub_CNT3, and a fourth sub-counter Sub_CNT4. Each of the first to fourth sub-counters Sub_CNT1, Sub_CNT2, Sub_CNT3, and Sub_CNT4 may have an output corresponding to a reset signal Reset, an oscillation signal OSC, and another sub-count signal (first, second, or third sub-count signal CNT1, CNT2, or CNT3).

For example, the first sub-counter Sub_CNT1 may receive the oscillation signal OSC and the reset signal Reset and output the first sub-count signal CNT1. The second sub-counter Sub_CNT2 may receive the first sub-count signal CNT1 and the reset signal Reset and output the second sub-count signal CNT2. The third sub-counter Sub_CNT3 may receive the second sub-count signal CNT2 and the reset signal Reset and output the third sub-count signal CNT3. The fourth sub-counter Sub_CNT4 may receive the third sub-count signal CNT3 and the reset signal Reset and output a fourth sub-count signal CNT4. The first to fourth sub-count signals CNT1, CNT2, CNT3, and CNT4 may be input to a NAND gate, and the NAND gate may output the counter output signal COUT. In this case, a target set value may have an arbitrary number by adding an inverter to a corresponding input terminal of the NAND gate.

In one embodiment, when the first to third sub-count signals CNT1, CNT2, and CNT3 are high while the fourth sub-count signal CNT4 is low, the counter output signal COUT may be low. In this case, the counter output signal COUT may be changed from high to low at the 7^{th} oscillation. Accordingly, in a similar way to FIG. 7A, in a case where the input voltage Vin has been increased 7 times, it may be determined that a corresponding word line of a semiconductor memory device to be checked is bad.

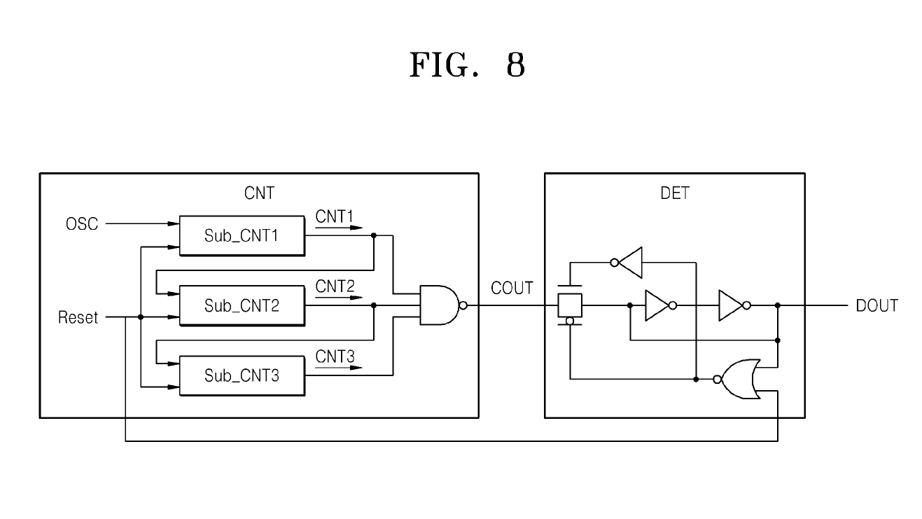

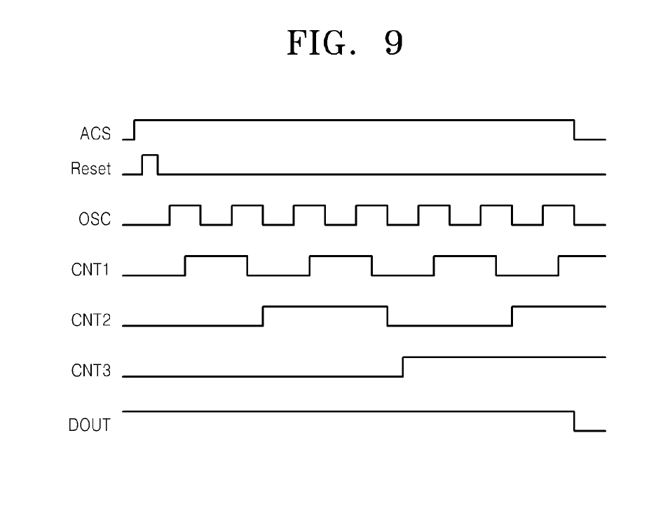

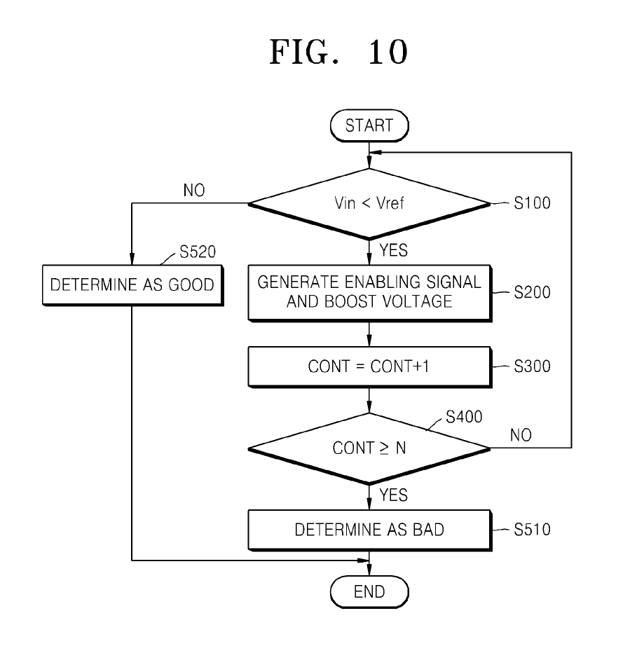

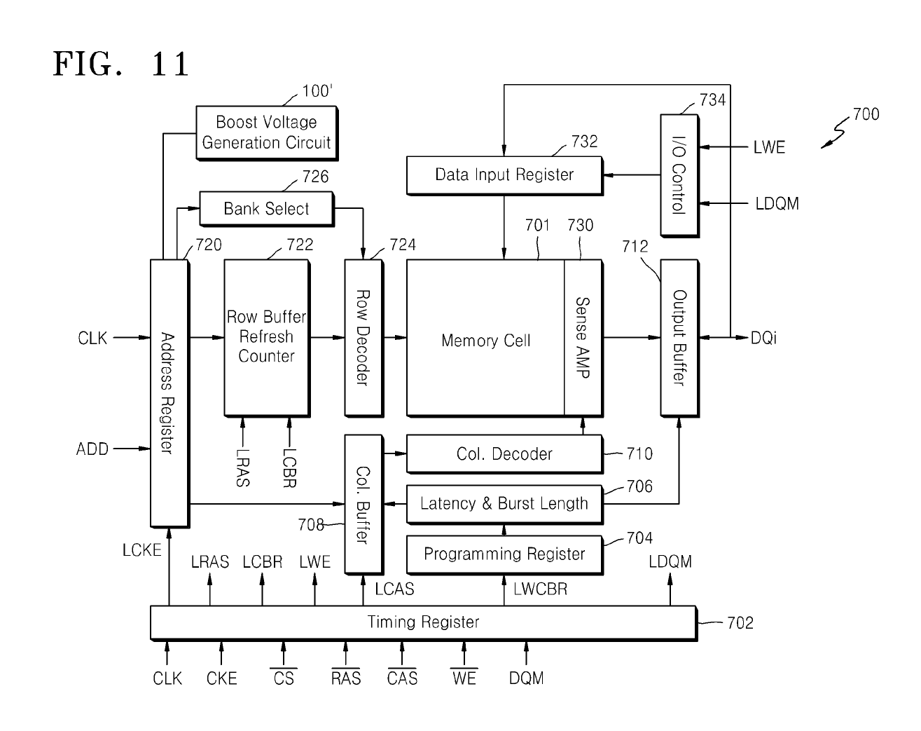

FIG. 8 is a block diagram of the counter CNT and the determiner DET included in a boost voltage generation circuit, according to an embodiment. FIG. 9 is a timing diagram illustrating an operation of the device of FIG. 8 according to an embodiment.

Referring to FIG. 8, although the counter CNT is the same as FIG. 7A, this is only illustrative, and the counter CNT of FIG. 8 may be replaced with the counter CNT of FIG. 7B or another counter CNT. The determiner DET of FIG. 8 is also illustrative. Thus, the counter CNT and the determiner DET do not limit the scope of the disclosure.

Referring to FIGS. 8 and 9, the enabling signal ACS may be activated during a predetermined period. For example, the predetermined period may be started by receiving an active command and may be ended by receiving a precharge command from a controller (not shown). The reset signal Reset is generated in response to the enabling signal ACS. The reset signal Reset is generated as a pulse signal having a high level. The quality output signal DOUT may be output as latched a count output signal COUT by the reset signal Reset. In addition, each of the first to third sub-counters Sub_CNT1, Sub_CNT2, and Sub_CNT3 may be reset by the reset signal Reset. The oscillation signal OSC may start to oscillate in response to the reset signal Reset.

A rising edge of a first pulse of the oscillation signal OSC causes the first sub-count signal CNT1 to be high. A rising edge of a second pulse of the oscillation signal OSC causes the first sub-count signal CNT1 to be low again. That is, the first sub-count signal CNT1 is triggered in response to rising edges of the oscillation signal OSC.

The second sub-count signal CNT2 is triggered in response to falling edges of the first sub-count signal CNT1. That is, the second sub-count signal CNT2 is high in response to a falling edge of a first pulse of the first sub-count signal CNT1 and is low in response to a falling edge of a second pulse of the first sub-count signal CNT1.

The third sub-count signal CNT3 is triggered in response to falling edges of the second sub-count signal CNT2. That is, the third sub-count signal CNT3 is high in response to a falling edge of a first pulse of the second sub-count signal CNT2.

In this case, a seventh pulse of the oscillation signal OSC causes the first to third sub-count signals CNT1 to CNT3 to be high. Accordingly, the counter output signal COUT of the NAND gate goes from high to low. In addition, the quality output signal DOUT changes from high to low. When an output of the determiner DET changes from high to low, an output of a NOR gate changes from low to high, thereby closing a switch of the determiner DET. When the quality output signal DOUT changes from high to low, it may be determined that the counted number of oscillation reaches the target set value because a corresponding word line may be shorted through a bit line and may have a micro bridge. Accordingly, it may be determined that a corresponding semiconductor memory device is bad.

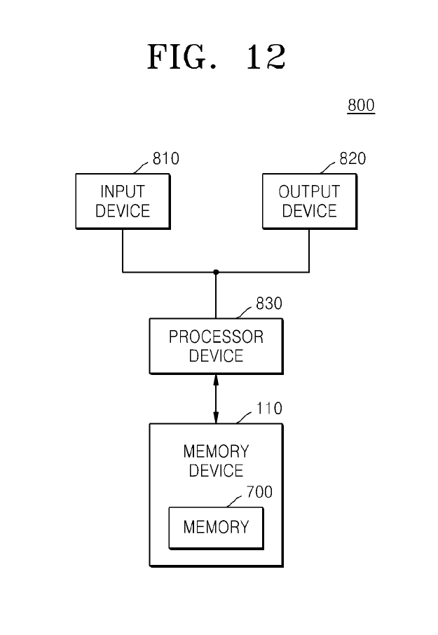

FIG. 10 is a flowchart illustrating a method of determining whether a semiconductor memory device is bad, according to an embodiment.

Referring to FIG. 10, in operation 5100, an input voltage Vin is compared with a reference voltage Vref. If the input voltage Vin is less than the reference voltage Vref, an enabling signal is generated, and a boost voltage is increased by a specific value than the input voltage Vin in operation 5200. In operation 5300, the counter CNT counts the number CONT of voltage boosting operations. In operation 5400, the counted number CONT is compared with a target set value N. If the counted number CONT is equal to and/or greater than the target set value N, it is determined in operation 5510 that the semiconductor memory device is bad. Otherwise, if the counted number CONT is less than (and/or not greater than) the target set value N, the boost voltage is fed back as the input voltage Vin to compare the input voltage Vin with the reference voltage Vref again in operation S100. If the input voltage Vin is less than the reference voltage Vref, the above operations are repeated, and if the input voltage Vin is equal to and/or greater than the reference voltage Vref, it is determined in operation S520 that the semiconductor memory device is good.

FIG. 11 is a block diagram of a Double Data Rate Synchronous Dynamic Random Access Memory (DDR-SDRAM) as an example of a semiconductor memory device 700 according to an embodiment. The boost voltage generation circuit 100′ according to the above disclosed embodiments may be included in the semiconductor memory device 700 as shown in FIG. 11. Referring to FIG. 11, the semiconductor memory device 700 may include a memory cell array 701 including DRAM cells, various circuit blocks for driving the DRAM cell, and the boost voltage generation circuit 100′. The boost voltage generation circuit 100′ is connected to a row decoder 724 as shown in FIG. 11. However, the boost voltage generation circuit 100′ may be connected to several circuits in a semiconductor memory device.

A timing register 702 may be enabled when a chip select signal CS changes from a disabled level (e.g., logic high) to an enabled level (e.g., logic low). The timing register 702 may receive command signals, such as a clock signal CLK, a clock enable signal CKE, a chip select signal, a row address strobe signal, a column address strobe signal CASB, a write enable signal WEB, and a data input/output mask signal DQM, from the outside and may generate various internal command signals LRAS, LCBR, LWE, LCAS, LWCBR, and LDQM for controlling the circuit blocks by processing the received command signals.

Some of the internal command signals LRAS, LCBR, LWE, LCAS, LWCBR, and LDQM generated by the timing register 702 are stored in a programming register 704. For example, latency information and burst length information related to a data output may be stored in the programming register 704. The internal command signals stored in the programming register 704 may be provided to a latency and burst length controller 706, and the latency and burst length controller 706 may provide a control signal for controlling a latency or a burst length of a data output to a column decoder 710 via a column buffer 708 or to an output buffer 712.

An address register 720 may receive an address signal ADD from the outside. A row address signal may be provided to a row decoder 724 via a row buffer/refresh counter 722. In addition, a column address signal may be provided to the column decoder 710 via the column buffer 708. The row buffer/refresh counter 722 may further receive a refresh address signal generated by a refresh counter in response to a refresh command LRAS or LCBR and may provide any one of the row address signal and the refresh address signal to the row decoder 724. In addition, the address register 720 may provide a bank signal for selecting a bank to a bank selector 726.

The row decoder 724 may decode the row address signal or the refresh address signal input from the row buffer/refresh counter 722 and enable a word line of the memory cell array 701. The boost voltage generation circuit 100′ may be connected to the row decoder 724 to supply a boost voltage to a respective word line of the memory cell array 701. The column decoder 710 may decode the column address signal and perform an operation of selecting a bit line of the memory cell array 701. For example, a column selection line signal may be applied to the semiconductor memory device 700 to perform a selection operation through the column selection line.

A sense amplifier 730 may amplify data of a memory cell selected by the row decoder 724 and the column decoder 710 and provide the amplified data to the output buffer 712. Data for writing on a memory cell may be provided to the memory cell array 701 via a data input register 732, and an input/output controller 734 may control a data transfer operation through the data input register 732.

FIG. 12 is a block diagram of an application example of an electronic system 800 including a semiconductor memory device 110, according to an embodiment.

Referring to FIG. 12, the electronic system 800 includes an input device 810, an output device 820, a processor device 830, and the semiconductor memory device 110. The processor device 830 may control the input device 810, the output device 820, and the semiconductor memory device 110 through corresponding interfaces. The processor device 830 may include at least one of at least one microprocessor, a digital signal processor, a microcontroller, and logic devices capable of performing similar functions of them. The input device 810 and the output device 820 may include at least one selected from a keypad, a keyboard, and a display device.

The semiconductor memory device 110 may include a volatile memory device, such as the DDR-SDRAM of FIG. 11, or a nonvolatile memory device, such as a flash memory. The semiconductor memory device 110 may include the boost voltage generation circuit 100′ according to the embodiments disclosed above.

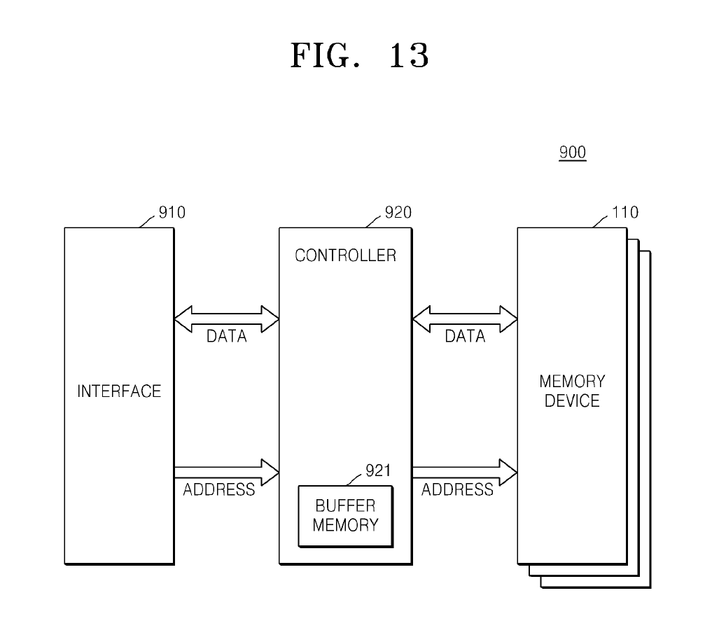

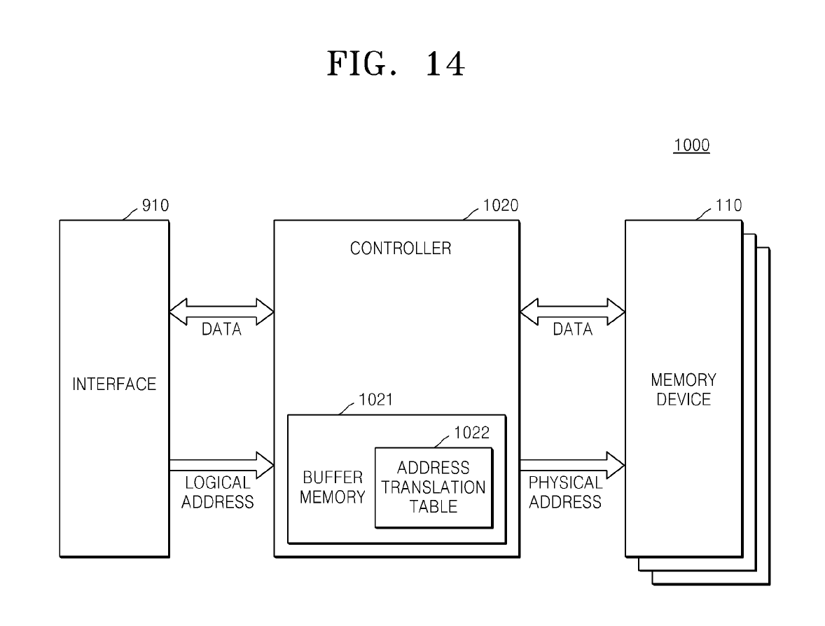

FIG. 13 is a block diagram of a first application example of a memory system 900 including the semiconductor memory device 110, according to an embodiment.

Referring to FIG. 13, the memory system 900 may include an interface unit 910, a controller 920, and the semiconductor memory device 110. The interface unit 910 may provide an interface between the memory system 900 and a host (not shown). The interface unit 910 may use a data exchange protocol corresponding to the host to interface with the host. The interface unit 910 may be configured to communicate with the host by using any one of various interface protocols, such as Universal Serial Bus (USB), Multi-Media Card (MMC), Peripheral Component Interconnect-Express (PCI-E), Serial-attached SCSI (SAS), Serial Advanced Technology Attachment (SATA), Parallel Advanced Technology Attachment (PATA), Small Computer System Interface (SCSI), Enhanced Small Disk Interface (ESDI), and Integrated Drive Electronics (IDE).

The controller 920 may receive data and an address from the host via the interface unit 910. The controller 920 may access the semiconductor memory device 110 by referring to the data and the address provided from the host. The controller 920 may provide data read from the semiconductor memory device 110 to the host via the interface unit 910.

The controller 920 may include a buffer memory 921. The buffer memory 921 temporarily stores write data provided from the host or data read from the semiconductor memory device 110. If data in the semiconductor memory device 110 is cached when the host requests reading, the buffer memory 921 supports a cache function for directly providing the cached data to the host. In general, a data transfer speed according to a bus format (e.g., SATA or SAS) of the host may be much faster than a data transfer speed in a memory channel of the memory system 900. That is, when an interface speed of the host is much faster than a data transfer speed in a memory channel of the memory system 900, the buffer memory 921 may be provided to minimize a performance decrease occurring due to the speed difference.

The semiconductor memory device 110 may include the boost voltage generation circuit 100′ according to embodiments disclosed above.

The semiconductor memory device 110 may be provided as a storage medium. For example, the semiconductor memory device 110 may be implemented by a resistive memory device. Alternatively, the semiconductor memory device 110 may be implemented by a NAND-type flash memory having a large storage capacity. The semiconductor memory device 110 may include a plurality of memory devices. For the semiconductor memory device 110 as a storage medium, a Parameter RAM (PRAM), a Magnetoresistive RAM (MRAM), a Resistive RAM (ReRAM), a Ferroelectric RAM (FRAM), or a NOR flash memory may be used, and the semiconductor memory device 110 may also be applied to a memory system in which different memory devices are used.

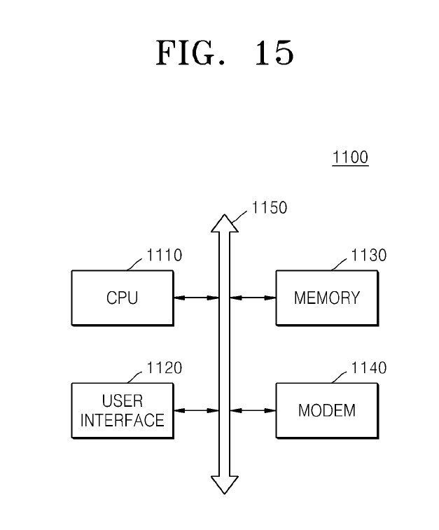

FIG. 14 is a block diagram of a second application example of a memory system 1000 including the semiconductor memory device 110, according to another embodiment.

Referring to FIG. 14, the memory system 1000 may include the interface unit 910, a controller 1020, and the semiconductor memory device 110. The interface unit 910 may use a data exchange protocol corresponding to a host (not shown) to interface with the host, as described with reference to FIG. 13. The semiconductor memory device 110 may be configured by a Solid State Disk (SSD) including the boost voltage generation circuit 100′ disclosed above. The memory system 1000 may be called a flash memory system.

The controller 1020 may include a buffer memory 1021 including an address conversion table 1022. The controller 1020 may convert a logical address provided from the interface unit 910 to a physical address by referring to the address conversion table 1022. The controller 1020 may access the semiconductor memory device 110 by referring to the physical address.

The memory system 900 or 1000 shown in FIG. 13 or 14 may be included in information processing devices, such as a Personal Digital Assistant (PDA), a portable computer, a web tablet, a digital camera, a Portable Media Player (PMP), a mobile phone, a wireless phone, and a laptop computer. The memory system 900 or 1000 may be configured by a Multi-Media Card (MMC), a Secure Digital (SD) card, a micro SD card, a memory stick, an Identification (ID) card, a Personal Computer Memory Card International Association (PCMCIA) card, a chip card, a USB card, a smart card, or a Compact Flash (CF) card.

FIG. 15 is a block diagram of a computer system 1100 including a semiconductor memory device, according to an embodiment.

Referring to FIG. 15, the computer system 1100 may include a Central Processing Unit (CPU) 1110, a user interface 1120, a memory 1130, and a modem 1140 such as a baseband chipset, which are electrically connected to a system bus 1150. The user interface 1120 may be an interface for transmitting or receiving data to or from a communication network. The user interface 1120 may be a wired/wireless type interface and may include an antenna or a wired/wireless transceiver. Data provided through the user interface 1120 or the modem 1140 or processed by the CPU 1110 may be stored in the memory 1130.

The memory 1130 may include a volatile memory device, such as a DRAM, and/or a nonvolatile memory device, such as a flash memory. The memory 1130 may include the boost voltage generation circuit 100′ disclosed above. The memory 1130 may be configured by a DRAM, a PRAM, an MRAM, an ReRAM, an FRAM, a NOR flash memory, a NAND flash memory, or a fusion flash memory (e.g., a memory in which an SRAM buffer, a NAND flash memory, and a NOR interface logic are combined).

When the computer system 1100 according to the current embodiment is a mobile device, a battery (not shown) for supplying an operation voltage of the computer system 1100 may be further provided. Although not shown, the computer system 1100 according to the current embodiment may further include an application chipset, a Camera Image Processor (CIP), an input/output device, etc.

When the computer system 1100 according to the current embodiment is a wireless communication device, the computer system 1100 may be used in communication systems, such as Code Division Multiple Access (CDMA), Global System for Mobile communication (GSM), North American Multiple Access (NADC), and CDMA2000.

While the disclosure has been particularly shown and described with reference to exemplary embodiments thereof, it will be understood that various changes in form and details may be made therein without departing from the spirit and scope of the following claims.

What is claimed is:

1. A semiconductor memory device comprising:
a voltage comparator configured to generate an enabling signal responsive to a comparison indicating that a first voltage is lower than a reference voltage;
a voltage generator configured to generate oscillation signals and a boost voltage by boosting the first voltage and to feed the boost voltage back as the first voltage in response to the enabling signal;
a counter configured to count the number of the oscillation signals, and to generate a count output signal having information corresponding to the number of the oscillation signals; and
a circuit configured to output the count output signal as a quality output signal indicating the counted number relative to a target set value.

2. The semiconductor memory device of claim 1, further comprising:
an external terminal configured to provide the quality output signal indicating the semiconductor device is bad when the counted number is equal to or exceeds the target set value.

3. The semiconductor memory device of claim 1, wherein the counter includes an enable input configured to receive an input responsive to the oscillation signals.

4. The semiconductor memory device of claim 1, wherein the circuit is further configured to block the count output signal into the circuit when the counted number is equal to the target set value.

5. The semiconductor memory device of claim 1, wherein the counter includes an enable input configured to receive an input responsive to the enabling signal.

6. The semiconductor memory device of claim 1, wherein the counter comprises:
a first sub-counter configured to generate a first count signal by receiving a reset signal and an oscillation signal;
second to (k+1)th (k is a natural number equal to or greater than 1) sub-counters configured to generate second to (k+1)th count signals by receiving the reset signal and first to kth count signals, respectively; and
a logic circuit configured to output the count output signal based on the first through (k+1)th count signals.

7. The semiconductor memory device of claim 6, further comprising:
a first external terminal configured to output the first count signal;
second to (k+1)th external terminals configured to output the second to (k+1)th count signals.

8. The semiconductor memory device of claim 1, wherein the voltage generator comprises:
an oscillator configured to generate the oscillation signals in response to the enabling signal; and
a pumping circuit configured to generate the boost voltage in response to the oscillation signals.

9. The semiconductor memory device of claim 8, wherein the counter includes an enable input configured to receive an input responsive to the oscillation signals.

10. A semiconductor memory device of claim 1, further comprising:
a memory array including, word lines and memory cells operatively connected to a respective one of the word lines; and
a word line driver configured to connect the first voltage to a selected one of the word lines.

11. A memory device comprising:
a memory cell array including memory cells corresponding to a plurality of word lines;
a voltage comparator configured to generate an enabling signal resulting from a comparison indicating a first voltage is lower than a reference voltage;
an oscillator configured to generate oscillation signals in response to the enabling signal;
a voltage generator configured to generate a boost voltage by boosting the first voltage in response to the oscillation signals;
a counter configured to count the number of oscillation signals, and to generate a count output signal responsive to the number of the oscillation signals;
a circuit configured to output the count output signal as a quality output signal indicating whether the memory device is good or bad; and
a row decoder configured to provide the first voltage to a selected one of the word lines.

12. The memory device of claim 11, wherein the quality output signal indicates whether the counted number is equal to or less than a predetermined value.

13. The memory device of claim 12, wherein the quality output signal has a first logic level when the counted number is less than the predetermined value and has a second logic level opposite to the first logic level when the counted number is equal to the predetermined value.

14. The memory device of claim 13, wherein the circuit is further configured to block the count output signal into the circuit when the counted number is equal to the predetermined value.

15. A method for screening operation of a memory device, the method comprising:
comparing a first voltage with a reference voltage;
generating an enabling signal in response to the result of the comparing;
generating oscillation signals in response to the enabling signal;
boosting the first voltage in response to the oscillation signals;
counting the number of oscillation signals and outputting a count output signal in response to the counting; and
outputting the count output signal as a quality output signal indicating whether the memory device is bad.

16. The method of claim 15, wherein the quality output signal indicates whether the counted number is equal to or less than a predetermined number.

17. The method of claim 16, wherein the quality output signal has a first logic level when the counted number is less than the predetermined number and has a second logic level opposite to the first logic level when the counted number is equal to the predetermined number.

18. The method of claim 15, wherein the memory device is indicated as good when the quality output signal has a first logic level and the memory device is indicated as bad when the quality output signal has a second logic level opposite to the first logic level.

19. The method of claim 18, further comprising blocking the count output signal when the quality output signal has the second logic level.

20. The method of claim 15, wherein the screening operation is activated during a predetermined period, the predetermined period is enabled in response to an active command and disabled in response to a precharge command.
